(19) United States
(12) Patent Application Publication
(10) Pub. No.: US 2011/0038115 A1
(43) Pub. Date: Feb. 17, 2011

(54) Illumination Arrangement

(75) Inventor: Heikki Vilhelmi Halkosaari, Paimio (FI)

Correspondence Address: Nokia, Inc., 6021 Connection Drive, MS 2-5-520, Irving, TX, 75039, US

(73) Assignee: NOKIA CORPORATION, Espoo (FI)

(21) Appl. No.: 12/520,838

(22) PCT Filed: Dec. 22, 2006
(86) PCT No.: PCT/FI2006/000420

§ 371 Date: May 4, 2010

(51) Int. Cl. H05K 7/00; H01H 13/76

(52) U.S. Cl. 361/679.08; 200/5 A

(57) ABSTRACT

An arrangement comprising a printed wiring board (210) having a number of electrical contact areas on a surface thereof (216) and one or more indents or apertures (218) residing next to the contact areas, one or more diffractive light guides (214) respectively positioned to said one or more indents or apertures (218) so that the one or more diffractive light guides (214) at least partly reside below the surface level of the printed wiring board (210), and at least one light source (212) positioned on or next to the printed wiring board (210) for emitting light to the one or more diffractive light guides (214). Also a keypad assembly utilizing the arrangement and various uses thereof are presented.

### FIELD OF THE INVENTION

The invention generally concerns the technology behind illuminating desired objects of electric apparatuses. Especially the invention concerns deployment of light guide arrangements for conducting light towards a keypad of such apparatuses.

### BACKGROUND OF THE INVENTION

Electric appliances such as various portable apparatuses including mobile terminals, palmtop computers, multimedia/music (e.g. MP3/Windows Media Audio) players and personal digital assistants (PDA) are configured to communicate with the users thereof via various data reproduction and user input technologies. For data visualisation a display and for audio reproduction a number of loudspeakers are common choices to be either directly integrated with or at least functionally connectable to the apparatus, whereas for the receipt of control input either a number of (push-)buttons (or “keys”), switches, knobs, touch screen, touch pad or an array of multiple keys constituting a keypad or a keyboard are provided. Especially in the context of portable consumer apparatuses the size (shape and measurements) and weight of the apparatus are key factors in producing a favourable user experience. Thus the common trend drives towards minimizing those while still maintaining the overall usability (readability of the display, accessibility of various keys, etc) on a tolerable level. Simultaneously, power consumption shall be kept low so that the apparatuses can be used as long as possible without a need for changing the replaceable power source, charging e.g. a rechargeable battery, or connecting the device to the power outlet.

Due to the mobile nature of portable apparatuses they are often utilized in conditions with limited visibility due to darkness, fog, rain, snowfall, etc. Therefore e.g. certain displays are provided with necessary backlight, considering for example a liquid crystal (LCD) display, unless they inherently contain light-emitting elements like in the case of light emitting diodes (LED). Buttons, switches and especially keypad or keyboard keys may be hard to localize and identify from each other in the gloom or total darkness. Passive tactile guides such as different types of protrusions and grooves may be used in hand-held apparatuses to guide e.g. the fingertip of the user to a desired location on the apparatus housing. However, these are not sufficient solutions e.g. in cold weather conditions when the user is wearing a glove, which degrades the sense of touch in the fingertips. Thus also a keypad, a keyboard, and separate keys of the aforementioned apparatuses may be provided with illumination to overcome the above defect.

FIG. 1 a depicts one scenario in which a keypad structure of a mobile terminal includes an illumination arrangement. The upper surface of a printed circuit board 101 comprises a number of contact areas where at least two conductive strips 102 and 103 come close to each other. Supported over the board 101 and separated from it by a perforated insulation layer, or a “dome sheet”, 104 is an array of conductive domes 105 so that each conductive dome 105 lies above the conductive strips 102 and 103. A key mat 106 is located on top of the conductive domes. It is made of an elastic material and has a bulging protrusion 107 on top of each conductive dome. A perforated outer cover 108 comes on top of the aforementioned structural components so that each bulging protrusion 107 of the keymat protrudes slightly out through the holes in the outer cover.

The key mat 106 is made of translucent silicon rubber or some other suitable material that conducts light reasonably well so that a plurality of surface-mounted light emitting diodes (SM-LEDs) 109 can be used for illuminating. The SM-LEDs 109 are soldered to contact pads 110 and 111 so that in the assembled configuration their principal direction of emission is through an edge of the key mat 106 into the substance thereof. Light escaping through the upper surfaces of the bulging protrusions 107 provides the visual illuminating effect seen by the user. The upper surfaces of the bulging protrusions 107 may be partly covered with an opaque layer so that light can only escape through an opening that may have the outline of a character or a group of characters. Fig. lb shows the same structure in assembled configuration.

FIG. 1c shows a simple circuit diagram of the illumination arrangement; the keypad functionality is not shown in FIG. 1c. The SM-LEDs 109 used for illumination constitute a serially coupled chain, the cathode side end of which is coupled to ground potential. The anode side end of the chain is coupled to a microprocessor 120 that comprises a controllable switch 121 between the anode side end of the SM-LED chain and a positive supply voltage Vcc. The microprocessor 120 comprises also means 122 for detecting the need for illumination of the keypad. The block 122 shown in FIG. 1c is typically a software process arranged to monitor the functional state of the keypad-controlled device in question and to generate an output pulse that closes the switch 121 whenever the functional state suggests that illumination of the keypad would be advantageous.

Light guides are devices that convey light from a source, e.g. a lamp, to a desired destination. They can be made of transparent film, plastic optical fibre or a combination of Teflon tube and a polymer core, for example. Sometimes a plurality of optical fibres is used together to form a bundle that may be split into several branches conducting light to multiple locations, respectively.

In an alternative solution, the top layer of the keypad has transparent or translucent portions or openings between the keys to project light from a dedicated light guide layer below. The light guide layer is made of material able to convey light to desired positions from a light source such as the aforesaid LED.

The above solutions comprise an increased number of layers, which adds to the overall thickness and weight of the keypad arrangement. Further, if placed too close to the dome keys, the LEDs may negatively affect the tactile feel.

Electroluminescent (EL) panel or film has been recently used to provide thin and uniform lighting to keypads of various electric appliances. EL lamps are light-emitting capacitors with a phosphor layer between two electrodes that is driven by

AC current obtained from DC to AC converters. EL lamps are relatively thin (e.g. 0.x mm), flexible and efficient what comes to the power consumption thereof. They may be even placed below each key without seriously interfering the pressing action. EL lamps, however, require a high voltage that must be created within the mobile device thus increasing the complexity of the required circuit arrangement. Accordingly, the price of the keypad with EL lighting shoots up.

### SUMMARY OF THE INVENTION

For illumination of desired objects such as keys of a keypad, it is provided an arrangement wherein a diffractive light guide and a light source accompany a preferably flexible printed wiring board (Flexible PWB). Alternatively, a rigid printed wiring board may be used as described hereinafter.

An arrangement according to one aspect of the invention comprises
a printed wiring board having a number of electrical contact areas on a surface thereof and one or more indents or apertures residing next to the contact areas,
one or more diffractive light guides respectively positioned to said one or more indents or apertures so that the one or more diffractive light guides at least partly reside below the surface level of the printed wiring board, and
at least one light source positioned on or next to the printed wiring board for emitting light to the one or more diffractive light guides.

The above arrangement may be included in a keypad assembly further comprising:
a keymat with a plurality of manually operable keys, and
an insulation sheet located between said keymat and said printed wiring board, said insulation sheet accommodating a plurality of contact elements related to said keys, respectively, mounted to confront the corresponding electrical contact areas on the printed wiring board for switching an associated electric circuit upon operation of a corresponding key.

A device comprising the aforesaid arrangement or assembly may be an electronic apparatus configured to receive control input via manual user input means such as a keypad in order to carry out the tasks associated with the input. Such electronic apparatus may be a mobile terminal, a palmtop computer, a personal digital assistant, a dictation machine, a music player, a cordless telephone, etc.

In the above, the keymat may comprise an elastic layer and a more rigid cover or support layer, optionally with perforations as in shown in FIG. 1.

The term “indent” refers herein to a dent, a cut-out, a groove, a cut, etc on the flexible printed wiring board.

The term “switching” refers herein to opening or closing a circuit.

The invention enables producing keypads and other illuminated structures that are still thin, reliable, and functionally substantially transparent from the user's standpoint what comes to the resulting tactile feel. Use of diffractive light guides provides good light emission properties with low loss.

In an embodiment a portable device such as a mobile terminal with the above keypad arrangement is provided and various alternative or supplementary features are presented to carry out a feasible implementation thereof.

### BRIEF DESCRIPTION OF THE RELATED DRAWINGS

Below, embodiments of the invention are described in more detail with reference to the attached drawings in which

FIG. 1a illustrates a keypad structure in exploded view,

FIG. 1b illustrates the keypad structure of FIG. 1a in assembled configuration,

FIG. 1c illustrates certain electric characteristics of the illumination arrangement of the structure of FIGS. 1a and 1b,

FIG. 2 depicts an embodiment of the invention wherein a portable electronic apparatus is provided with the keypad assembly of the invention,

FIG. 3 illustrates positioning light guides on a printed wiring board,

FIG. 4A depicts light leak from the light guide towards the surrounding structures and keymat,

FIG. 4B depicts coupling of the light source to the light guide.

FIG. 5 is a block diagram representing an example of an electronic apparatus capable of utilizing the invention.

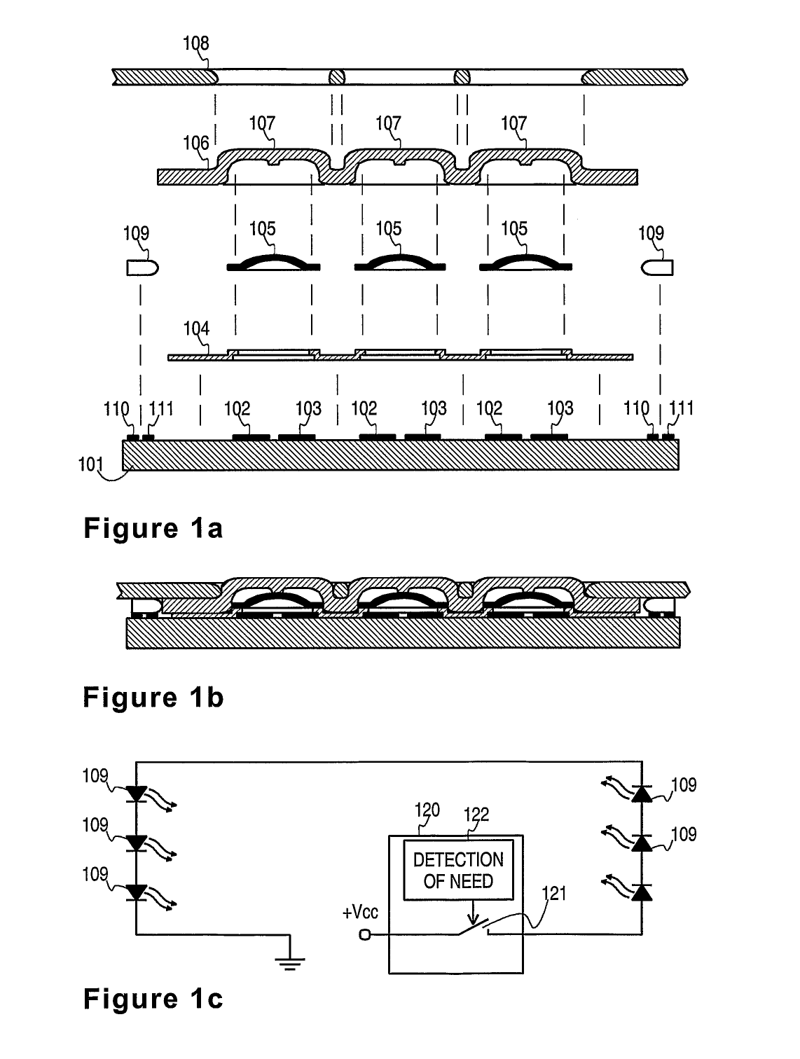

### DETAILED DESCRIPTION OF THE EMBODIMENTS

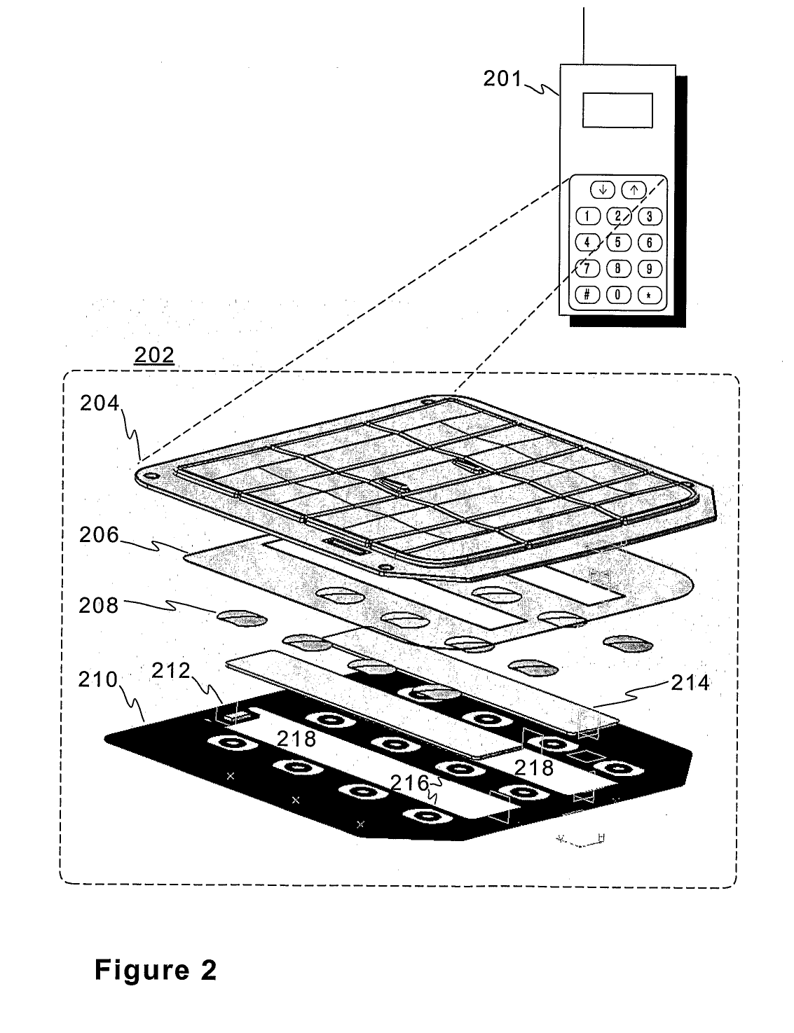

FIG. 2 discloses a conceptual view of one embodiment of the keypad assembly 202 in accordance with the invention. The assembly 202 may be provided as a keypad module, for example, and included e.g. in a portable apparatus such as a mobile terminal 201. It comprises a keymat 204 that is a structure accommodating a plurality of keys.

The keymat 204 may be constructed utilizing a single or a plurality of different materials; in the latter case the key protrusions may be made of more rigid material whereas the remaining structure is at least partially elastic. The keymat 204 may be supported and also partially covered by a support structure, e.g. a grid that may belong to the general cover structure of the portable device. The keymat 204 may include one or more grooves that separate the key “forms” or protrusions from each other to facilitate their individual activation and light emission from the lower layers. Further, the keymat 204 may comprise transparent or translucent material to convey the light from the lower layers. In addition to push-down keys the keymat 204 may accommodate other types of actuators, e.g. a roller key or a rocker key.

Associated with each key the keymat structure 204 may include a protruding element called a plunger that projects from the keymat to the direction of the sheet 206 to activate the corresponding contact element, e.g. a dome 208, when the user of the apparatus depresses the related key. The dome 208 then deflects or deforms in response to force introduced thereto and switches the electric circuit below via the electrical contact areas 216 on a preferably flexible printed wiring board 210. The domes 208 may be e.g. hemispherical or “D-cut” domes.

A insulation sheet 206 often called a “dome sheet” as it accommodates the domes 208, can be at made, at least partially, of transparent or translucent material so that it conveys the light from the diffractive light guides 214 towards the desired locations such as the keys. Additionally or alternatively, the sheet 206 may include apertures or indents that directly enable light propagation from the diffractive light guides 214 forward and/or accommodate top part of the light guides 214, i.e. the cross-sectional top area, projecting from the indents or apertures of the flexible printed wiring board 210 as a result of which the addition of light guides to the structure does not increase the overall thickness of the keypad assembly, not at least as much as without such deployment technique. The sheet 206 may be thin, a film-like.

The flexible printed wiring board 210 is manufactured using materials that tolerate flexing or bending. Flex substrates are thin and the used materials may include e.g. polyimide and polyester. The flexible printed wiring board 210 includes electrical contact areas 216 co-operating with the domes 208 to form switches, and indents or apertures 218 that enable positioning the diffractive light guides 214 within the surrounding structural layers without a need for an additional one. As flexible printed wiring board 210 may be only a few tenths of millimetres thick (e.g. 0.2 mm or even less), the aperture 218 in a form of a through-hole may be easier to arrange on the board 210 than a mere indent.

However, instead of a flexible printed wiring board also a rigid one 210 can be used in the context of the present invention, although the resulting arrangement or assembly 202 could be thicker then. For example, modern so-called 3D (technology) circuit boards (thickness between 0.8-1.2 mm, for example) can accommodate the light guides 214 in e.g. 0.2 mm deep dents or grooves so that the light guides 214 do not constitute to the overall thickness of the related arrangement or assembly 202.

A light source 212 such as a LED or a light bulb may be attached to the printed wiring board 210 or a near-by object so that the emitted light is funnelled into the one or more diffractive light guides 214. The LED may be selected so as to emit light of any realizable colour, e.g. red or green. Also colour filters may be used for coloring the light emitted by a white light source. Only a single or multiple light sources 212 may be used depending on the number and location of diffractive light guides 214, for example.

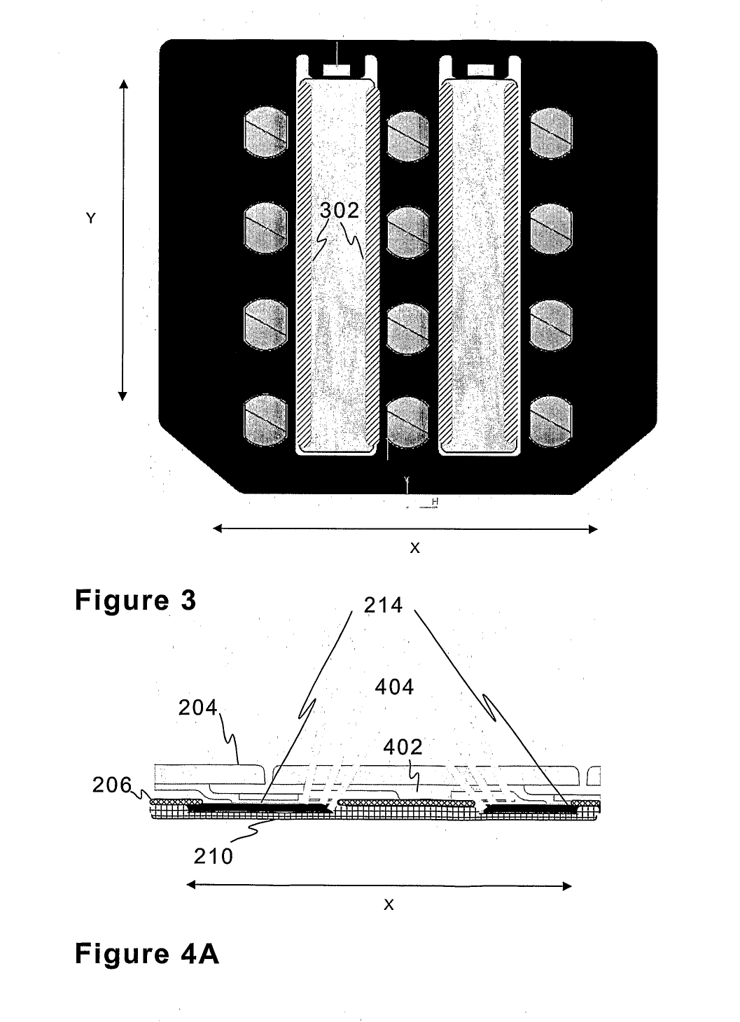

With reference to FIG. 3 representing a top face view of the flexible printed wiring board 210, the diffractive light guides 214 may be manufactured as elongated elements designed so as to the provide the desired, optimal light leak from the sides 302 thereof (notice the light-emitting portions highlighted in the figure with a diagonal line fill) towards the keypad assembly surface. The light guides 214 may be further attached to the printed wiring board 210 by utilizing one or more predetermined structural features of the board 210 such as different protrusions or dents designed for the purpose. Alternatively or in addition, the sandwich structure of the keyboard assembly as such maintains the light guides well enough in a desired position in relation to the domes or other predetermined surrounding elements.

The light guides 214 may comprise a thin film or foil (e.g. 0.1-0.2 mm, nonetheless less than 0.7 mm) that optionally includes predetermined light escaping areas (e.g. on sides as shown in the figure) provided by a special coating and/or texture or a surface pattern, which may be microscopic, introduced thereto. Such pattern can be generated by driving a film through a pair of rollers that act like printing plate(s) in this case. Alternatively or in addition, the light guides 214 may incorporate optical fibres, for example.

Preferably the electrical contact areas 216 (and related domes) have some physical distance in relation to each other on the printed wiring board 210 such that there is enough clearance to properly position the diffractive light guides 214 between them for achieving the desired illumination effect.

Optionally light-leakage protectors such as reflectors, masks, frames, or other structures can be utilized to prevent undesired light leaking from the light guide 214 to predetermined areas. Such protectors may be dedicated elements or parts of existing structures originally having also some other function, e.g. a support or anchor function for other structures. The protectors may, for example, constitute a frame structure that surrounds the flexible wiring board 210 and/or forms partition walls therein.

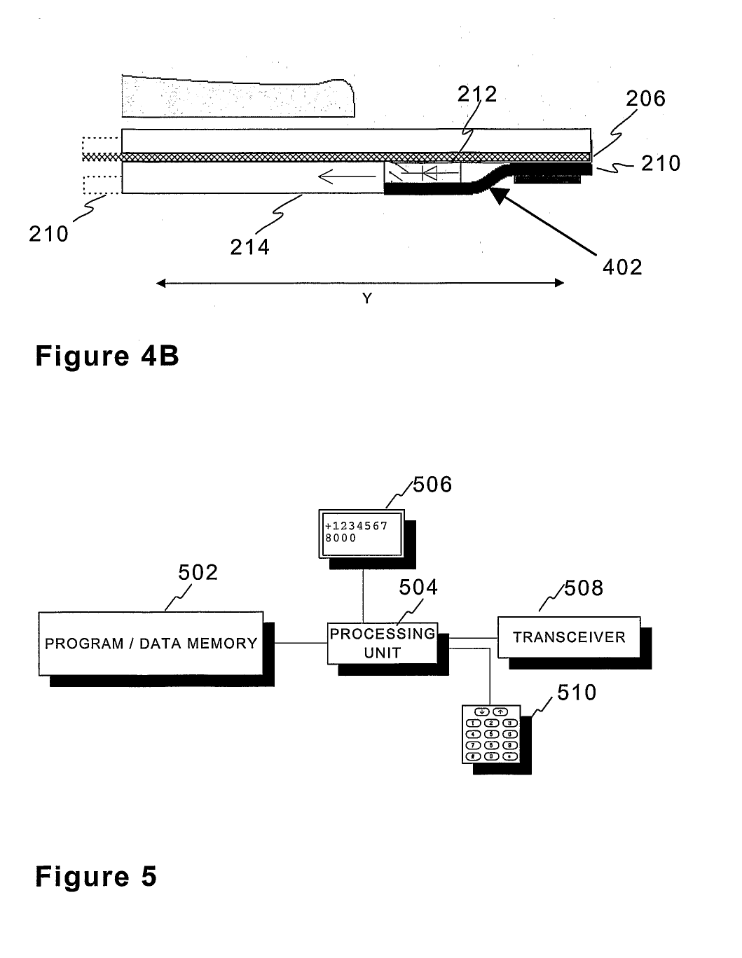

FIG. 4A depicts a cross-sectional view of the keypad assembly including the printed wiring board 210, dome sheet 206, diffractive light guide 214, and keymat 204 with plunger 402 targeted towards the associated dome and electrical contact area on the board 210 (not explicitly shown in the figure for clarity). Beams of light 404 emanating from the border areas of the light guide 214 propagate through the upper layers towards the keypad surface for illuminating at least part thereof provided that necessary openings and/or transparent or translucent material are arranged to the optical path.

FIG. 4B represents another cross-sectional view of one option for the coupling between the light source 212 and the diffractive light guide 214. The light source 212, e.g. a LED as depicted in the figure, may be positioned in a dent 402 of the (flexible) printed wiring board 210 so that the LED at least partially resides below the corner level of the printed wiring board 210. The diffractive light guide 214 has been embedded in the aperture of the flexible printed wiring board 210 according to one embodiment of the invention and positioned and aligned so as to capture and convey the light emitted by the LED 212 (light direction depicted as an arrow in the LED block 212).

Both the circuit board arrangement including the diffractive light guides 214 and the keypad assembly 202 according to the invention may be provided as such to a party who takes cares of fabrication of the end product whereto the circuit board or assembly 202 comprising the circuit board are installed. Alternatively, the arrangement may be provided together with domes 208 (and dome sheet 206) but without the keymat 204 and various layers thereof, the selection and acquisition of which can be then left to the final or intermediate assembling party.

During the manufacture of the arrangement according to the invention, the (flexible) printed wiring board 210 is produced and provided with means, e.g. an aperture or a dent, for accommodating at least part of the associated diffractive light guides 214, which are then positioned to such means. Upper layers including the dome sheet 206 and keymat 204 are superimposed on the board 210 accommodating the light guides 214.

An electronic apparatus, an example of which in a form a portable device is shown in FIG. 5, comprising the aforesaid arrangement or assembly 202 may further comprise a processing unit 504 (e.g. a microprocessor, a (digital) signal processor, a programmable logic array, a microcontroller, or a plurality of those) and a memory 502 (e.g. one or more memory chips or cards) for processing and storing instructions and data. The apparatus may be then configured to receive control input from a user via a keypad 510 incorporating the arrangement or assembly of the invention and to carry out a task associated with the received input. The electronic apparatus may further comprise a display 506 for visualizing information related to the carried out task, for example, and a power source for powering e.g. the keypad assembly 202 including said at least one light source and the required electric circuits. The apparatus may also comprise a communication means 508 such as a (wireless) transceiver for communicating with other devices.

The circuit arrangement of the invention may be potentially utilized also for various other purposes than the aforesaid illumination of keypad in the context of portable apparatuses. In general sense, the indents or apertures for receiving the diffractive light guides 214 may be manufactured so as to situate alongside the electrical contacts that or the vicinity of which shall be illuminated.

The above-described exemplary embodiments of the invention should be construed as an aid for comprehending the applicability of the claims and not as explicit limitations regarding such applicability. Directional expressions such as “top face” refer only to the directions illustrated in the drawings and do not limit the applicability of the invention to structures only oriented in a certain direction.

1. An arrangement comprising
a printed wiring board having a number of electrical contact areas on a surface thereof and one or more indents or apertures residing next to the contact areas,
one or more diffractive light guides respectively positioned to said one or more indents or apertures so that the one or more diffractive light guides at least partly reside below the surface level of the printed wiring board, and
at least one light source positioned on or next to the printed wiring board for emitting light to the one or more diffractive light guides.

2-23. (canceled)

24. The arrangement according to claim 1, wherein said at least light source comprises a light emitting diode or a light bulb.

25. The arrangement according to claim 1, wherein said one or more diffractive light guides include a thin film or optical fibre.

26. The arrangement according to claim 1, wherein said one or more indents or apertures define a through-hole.

27. The arrangement according to claim 1, wherein said printed wiring board is one of: a flexible printed wiring board and a rigid 3D printed wiring board.

28. A keypad assembly comprising the arrangement according to claim 1, further comprising:
a keymat with a plurality of manually operable keys, and
an insulation sheet located between said keymat and said printed wiring board, said insulation sheet accommodating a plurality of contact elements related to said keys, respectively, mounted to confront the corresponding electrical contact areas on the printed wiring board for switching an associated electric circuit upon operation of a corresponding key.

29. The keypad assembly according to claim 28, wherein said contact elements are hemispherical domes.

30. The keypad assembly according to claim 28, wherein said keymat comprises elastic material.

31. The keypad assembly according to claim 28, wherein said keymat comprises transparent or translucent material.

32. The keypad assembly according to claim 28, wherein said keymat comprises a number of plungers configured to protrude towards the contact elements.

33. The keypad assembly according to claim 28, wherein said keymat comprises a number of grooves configured to separate keys from each other.

34. The keypad assembly according to claim 28, wherein said insulation sheet includes at least one indent or opening for accommodating at least part of an diffractive light guide belonging to said one or more diffractive light guides.

35. The keypad assembly according to claim 28, wherein said diffractive light guides are elongated and configured to leak light through the longitudinal side portions thereof.

36. The keypad assembly according to claim 28, further comprising one or more light-leak protectors for preventing light entering one or more predetermined areas of the assembly or outside the assembly.

37. An electronic apparatus comprising the arrangement according to claim 1.

38. The electronic apparatus according to claim 37, further comprising a processing unit and a memory for processing and storing instructions and data, configured to receive control input from a user via keypad and to carry out a task associated with the received input.

39. The electronic apparatus according to claim 38, further comprising a display for visualizing information related to the carried out task.

40. The electronic apparatus according to claim 37, further comprising a power source for powering the keypad assembly including said at least one light source and the electric circuits thereof.

41. The electronic apparatus according to claim 37 that is one of: a mobile terminal, a palmtop computer, a personal digital assistant, a portable dictation machine, a portable music player and a cordless telephone.
